(19) United States
(12) Patent Application Publication
(10) Pub. No.: US 2022/0342266 A1
(43) Pub. Date: Oct. 27, 2022

(54) Array Substrate and Display Apparatus

(71) Applicants: CHONGQING BOE OPTOELECTRONICS TECHNOLOGY CO., LTD., CHONGQING (CN); BOE TECHNOLOGY GROUP CO., LTD., Chaoyang District, Beijing (CN)

(72) Inventors: Jingyong Hu, Beijing (CN); Zhe Li, Beijing (CN); Jingyu Wang, Beijing (CN); Jiantao Liu, Beijing (CN)

(21) Appl. No.: 17/762,952

(22) PCT Filed: May 12, 2021
(86) PCT No.: PCT/CN2021/093322

§ 371 Date: Mar. 23, 2022

(30) Foreign Application Priority Data
Jun. 28, 2020 (CN) 202010597870.7

(51) Int. Cl. G02F 1/1362; G02F 1/1333; G02F 1/1343; H01L 27/12

(52) U.S. Cl. CPC G02F 1/136286; G02F 1/133345; G02F 1/134309; G02F 1/13439; H01L 27/1248; G02F 1/1337

(57) ABSTRACT

Provided are an array substrate and a display apparatus. The array substrate comprises: a base substrate; a gate line on the base substrate; a first insulating layer covering the gate line; a data line on the first insulating layer; a second insulating layer covering the data line; a common electrode on the second insulating layer, the common electrode comprising a plurality of portions, wherein each portion comprises a plurality of strip-shaped electrodes, each strip shaped electrode comprising a first main body portion, a second main body portion, a first connecting portion and a second connecting portion, and the first main body portion comprising a first corner end portion; and a metal wire in the same layer as the gate line, wherein an orthographic projection of the first corner end portion on the base substrate exceeds an orthographic projection of the metal wire on the base substrate.

### CROSS-REFERENCE TO RELATED APPLICATIONS

The present application is the U.S. National Phase Application under 35 U.S.C. § 371 of International Patent Application No. PCT/CN2021/093322, filed on May 12, 2021, and claims priority to Chinese Patent Application No. 202010597870.7 filed on Jun. 28, 2020, the disclosures of both of which are incorporated by reference herein in their entirety.

### TECHNICAL FIELD

The present disclosure relates to an array substrate and a display device.

### BACKGROUND

The Fringe Field Switching (referred to as FFS) display technology is the mainstream display technology in the current liquid crystal display wide viewing angle display. In this display technology, the deflection of liquid crystal molecules is implemented by the fringe electric field between the pixel electrode and the common electrode on an array side, thereby realizing the display. In order to reduce the color cast of the liquid crystal display panel, a dual-domain electrode structure with a 1P2D architecture (i.e., 1 Pixel 2 Domain) is used in the related art.

### SUMMARY

According to an aspect of embodiments of the present disclosure, an array substrate is provided. The array substrate comprises: a base substrate; a gate line located on a side of the base substrate and extending along a first direction; a first insulating layer covering the gate line; a data line on a side of the first insulating layer away from the base substrate, the data line and the gate line defining a plurality of pixel areas; a second insulating layer covering the data line; a common electrode on a side of the second insulating layer away from the data line, wherein the common electrode comprises a plurality of portions corresponding to the plurality of pixel areas, each portion of the plurality of portions comprising a plurality of strip electrodes, a slit being provided between adjacent strip electrodes of the plurality of strip electrodes, each strip electrode of the plurality of strip electrodes comprising a first main body portion extending along a second direction, a second main body portion extending along a third direction, a first connecting portion extending along a fourth direction and a second connecting portion extending along a fifth direction, the first main body portion being connected to the first connecting portion, the second main body portion being connected to the second connecting portion, the first connecting portion being connected to the second connecting portion, the first connecting portion and the second connecting portion forming a first included angle, and the first main body portion comprising a first corner end; and a metal wire located in the same layer as the gate line and extending along the first direction, wherein an orthographic projection of the first corner end on the base substrate goes beyond an orthographic projection of the metal wire on the base substrate.

In some embodiments, a ratio of a width of the each strip electrode to a width of the slit ranges from 0.3 to 0.7.

In some embodiments, a range of the width W1 of the each strip electrodes is 2 microns≤W₁<2.8 microns.

In some embodiments, a range of the width W2 of the slit is 4 microns≤W₂<5.8 microns.

In some embodiments, a range of a sum H₁ of projection lengths of the first connecting portion and the second connecting portion on a direction perpendicular to the first direction is 3.9 microns≤H₁<5.9 microns.

In some embodiments, an inner side of a portion where the first connecting portion is connected to the second connecting portion is provided with a concave pattern, and an outer side of the portion where the first connecting portion is connected to the second connecting portion is provided with a convex pattern.

In some embodiments, an area of the concave pattern is equal to an area of the convex pattern.

In some embodiments, a shape of the concave pattern is the same as a shape of the convex pattern.

In some embodiments, the array substrate further comprises: a gate electrode in the same layer as the gate line, wherein the gate electrode is electrically connected to the gate line, and the gate electrode is covered by the first insulating layer; an active layer and a pixel electrode both on a side of the first insulating layer away from the base substrate, wherein the active layer is isolated from the pixel electrode; and a first electrode and a second electrode both on a side of the active layer away from the first insulating layer, wherein the first electrode and the second electrode are electrically connected to the active layer, and the first electrode, the second electrode, the active layer and the pixel electrode are covered by the second insulating layer; wherein the second main body portion comprises a second corner end, and an orthographic projection of the second electrode on the base substrate covers at least a portion of an orthographic projection of the second corner end of a portion of the plurality of strip electrodes on the base substrate.

In some embodiments, the array substrate further comprises: a first orientation layer covering the common electrode; a liquid crystal layer on a side of the first orientation layer away from the common electrode; a second orientation layer on a side of the liquid crystal layer away from the first orientation layer; a black matrix layer on a side of the second orientation layer away from the liquid crystal layer, wherein an orthographic projection of the black matrix layer on the base substrate covers an orthographic projection of the first corner end and a portion of the first main body portion adjacent to the first corner end on the base substrate; and a color film layer covering the black matrix layer and the second orientation layer.

In some embodiments, a range of a length L₀ of the portion of the first main body portion adjacent to the first corner end along the second direction is 0<L₀≤2.5 microns.

In some embodiments, an angle of a second included angle formed by the first corner end and the first direction is 40° to 50°.

In some embodiments, an angle of a third included angle formed by the second corner end and the first direction is 40° to 50°.

According to another aspect of embodiments of the present disclosure, a display device is provided. The display device comprises the array substrate as described previously.

Other features and advantages of the present disclosure will become apparent from the following detailed description of exemplary embodiments of the present disclosure with reference to the accompanying drawings.

### BRIEF DESCRIPTION OF THE ACCOMPANYING DRAWINGS

The accompanying drawings which constitute part of this specification, illustrate the exemplary embodiments of the present disclosure, and together with this specification, serve to explain the principles of the present disclosure.

The present disclosure may be more explicitly understood from the following detailed description with reference to the accompanying drawings, in which:

FIG. 1 is a top view showing a structure of a pixel of an array substrate for a liquid crystal display in the related art;

FIG. 2 is a top view showing an array substrate according to an embodiment of the present disclosure;

FIG. 3 is a schematic cross-sectional view showing a structure of an array substrate taken along a line C-C′ shown in FIG. 2 according to an embodiment of the present disclosure;

FIG. 4 is a schematic cross-sectional view showing a structure of an array substrate taken along a line D-D′ shown in FIG. 2 according to an embodiment of the present disclosure;

FIG. 5 is a partially enlarged view showing an array substrate at a block E in FIG. 2 according to an embodiment of the present disclosure;

FIG. 6 is a partially enlarged view showing an array substrate at a block F in FIG. 2 according to an embodiment of the present disclosure;

FIG. 7 is a partially enlarged view showing an array substrate at a block G in FIG. 2 according to an embodiment of the present disclosure.

It should be understood that the dimensions of the various parts shown in the accompanying drawings are not drawn according to the actual scale. In addition, the same or similar reference signs are used to denote the same or similar components.

### DETAILED DESCRIPTION

Various exemplary embodiments of the present disclosure will now be described in detail in conjunction with the accompanying drawings. The description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”, “include”, or the like means that the element before the word covers the element(s) listed after the word without excluding the possibility of also covering other elements. The terms “up”, “down”, “left”, “right”, or the like are used only to represent a relative positional relationship, and the relative positional relationship may be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to said other devices without an intermediate device, and alternatively, may not be directly connected to said other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

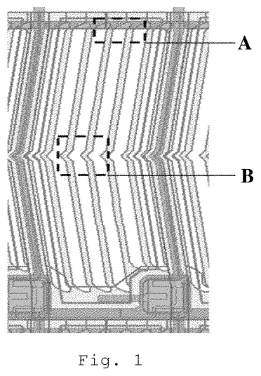

FIG. 1 is a top view showing a structure of a pixel of an array substrate in the related art . The array substrate is an array substrate of the liquid crystal display screen.

As shown in FIG. 1, in order to reduce the color cast problem of the liquid crystal display panel, a dual-domain electrode structure with a 1P2D architecture is used in the related art. The inventors of the present disclosure have found that, in the related art, in order to reduce the problem of Trace mura (uneven traces), a corner design (as shown at the position A in FIG. 1) is used in the fringe area of the pixel. However, such design causes an uneven electric field to be formed in in the area, thereby forming an uneven dark area, reducing the light efficiency of the liquid crystal, and further reducing the display effect.

In view of this, the embodiments of the present disclosure provide an array substrate for a liquid crystal display screen, so as to reduce the adverse impact of the corner design of the fringe area of the pixel on the display effect.

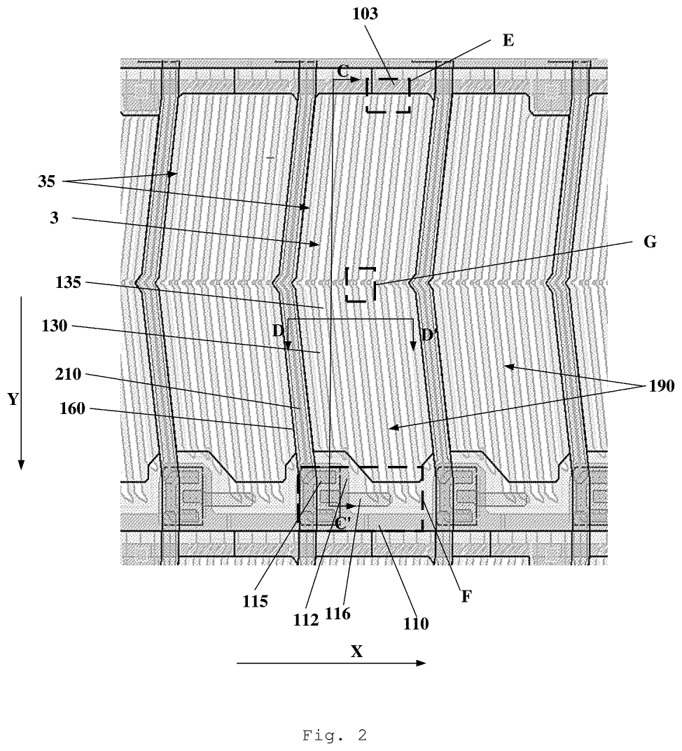

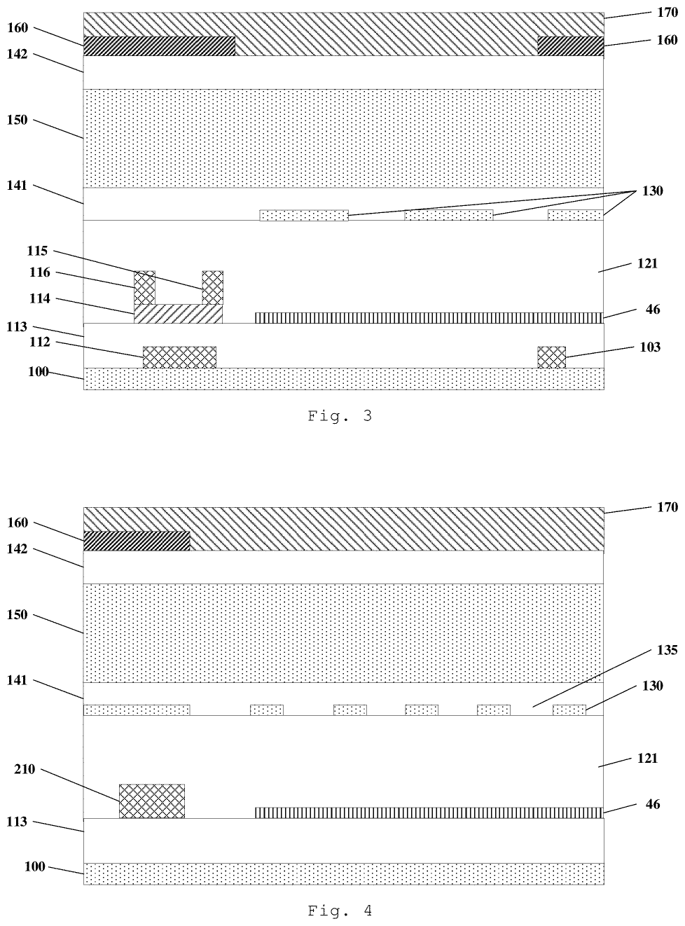

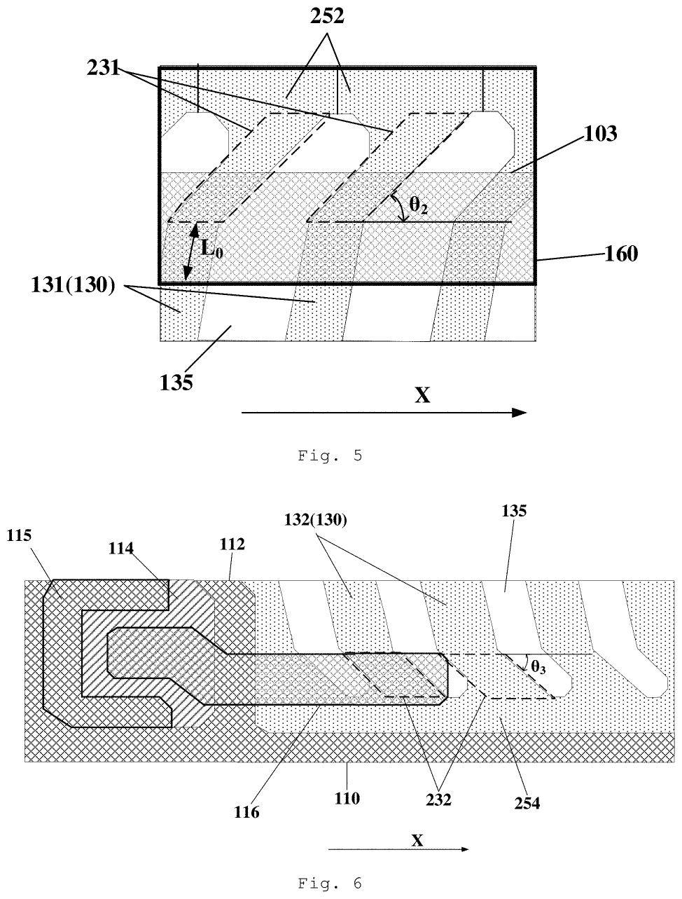

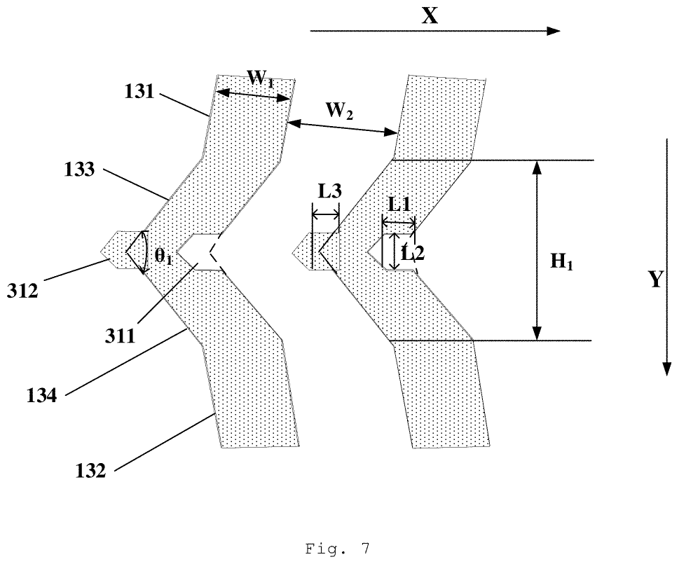

FIG. 2 is a top view showing an array substrate for a liquid crystal display screen according to an embodiment of the present disclosure. FIG. 3 is a schematic cross-sectional view showing a structure of an array substrate taken along a line C-C′ shown in FIG. 2 according to an embodiment of the present disclosure. FIG. 4 is a schematic cross-sectional view showing a structure of an array substrate taken along a line D-D′ shown in FIG. 2 according to an embodiment of the present disclosure. FIG. 5 is a partially enlarged view showing an array substrate at a block E in FIG. 2 according to an embodiment of the present disclosure. FIG. 6 is a partially enlarged view showing an array substrate at a block F in FIG. 2 according to an embodiment of the present disclosure. FIG. 7 is a partially enlarged view showing an array substrate at a block G in FIG. 2 according to an embodiment of the present disclosure.

It should be noted that, in order to facilitate showing the main features of the embodiments of the present disclosure, the structures of all layers are not shown in the top views of the embodiments of the present disclosure (e.g., FIGS. 2, 5, 6 and 7). Those skilled in the art can understand the structural relationship of various layers in these top views in conjunction with the cross-sectional views.

The structure of the array substrate according to some embodiments of the present disclosure will be described in detail below in conjunction with FIGS. 2 to 7.

As shown in FIGS. 2 and 3, the array substrate comprises a base substrate 100. For example, the base substrate comprises a glass substrate, a resin substrate, or the like.

As shown in FIGS. 2, 3 and 6, the array substrate further comprises a gate line 110 located on a side of the base substrate 100 and extending along a first direction X. For example, the gate line 110 (not shown in FIG. 3) is in the same layer as a gate electrode 112 (to be described later) of a thin film transistor. In some embodiments, the gate line 110 is integrally formed with the gate electrode 112. For example, a material of the gate line comprises metals such as molybdenum, aluminum, or copper.

As shown in FIG. 3, the array substrate further comprises a first insulating layer 113 covering the gate line 110. For example, a material of the first insulating layer 113 comprises silicon oxide, silicon nitride, or the like.

As shown in FIGS. 2 and 4, the array substrate further comprises a data line 210 on a side of the first insulating layer 113 away from the base substrate 100. For example, the data line 210 is formed through the same patterning process as a first electrode and a second electrode (to be described later) of the thin film transistor. As shown in FIG. 2, the data line 210 substantially extends along a direction Y (which may be referred to as a sixth direction) that is perpendicular to the first direction X. Those skilled in the art may understand that the data line 210 may not extend completely along the sixth direction Y. For example, since the data line 210 has a bent portion, the extending direction of the data line 210 may be offset from the direction Y, but the data line as a whole may be regarded as extending along the sixth direction Y. As shown in FIG. 2, the data line 210 and the gate line 110 define a plurality of pixel areas 190. Each pixel area corresponds to one pixel.

As shown in FIGS. 2 and 4, the array substrate further comprises a second insulating layer 121 covering the data line 210. For example, a material of the second insulating layer 121 comprises silicon oxide, silicon nitride, or the like.

As shown in FIGS. 2 and 4, the array substrate further comprises a common electrode 3 on a side of the second insulating layer 121 away from the data line 210. The common electrode 3 comprises a plurality of portions 35 corresponding to the plurality of pixel areas 190. Each portion 35 comprises a plurality of strip electrodes 130. A slit 135 is provided between adjacent strip electrodes of the plurality of strip electrodes 130.

As shown in FIG. 7, each of the plurality of strip electrodes 130 comprises a first main body portion 131 extending along a second direction, a second main body portion 132 extending along a third direction, a first connecting portion 133 extending along a fourth direction, and a second connecting portion 134 extending along a fifth direction. The second direction, the third direction, the fourth direction and the fifth direction are all different from each other. The first main body portion 131 is connected to the first connecting portion 133. The second main body portion 132 is connected to the second connecting portion 134. The first connecting portion 133 is connected to the second connecting portion 134. The first connecting portion 133 and the second connecting portion 134 form a first included angle θ₁. For example, the first included angle is less than 180°. As shown in FIGS. 2 and 5, the first main body portion 131 comprises a first corner end 231.

As shown in FIGS. 2, 3 and 5, the array substrate further comprises a metal wire 103 located in the same layer as the gate line 110 and extending along the first direction X. For example, a material of the metal wire 103 is the same as the material of the gate line. An orthographic projection of the first corner end 231 on the base substrate 100 goes beyond an orthographic projection of the metal wire 103 on the base substrate 100.

It should be noted here that, “goes beyond” herein means that the orthographic projection of the metal wire on the base substrate does not completely cover the orthographic projection of the first corner end on the base substrate. As shown in FIG. 5, the orthographic projection of the metal wire 103 on the base substrate 100 covers a part of an orthographic projection of a part of the first main body portion 131 connected to the first corner end 231 on the base substrate 100 and a part of the orthographic projection of the first corner end 231 on the base substrate 100. A remaining part of the orthographic projection of the first corner end 231 on the base substrate 100 does not overlap with the orthographic projection of the metal wire 103 on the base substrate 100, and the remaining part is on a side of the orthographic projection of the metal wire 103 on the base substrate 100 away from the first included angle θ₁.

In some embodiments, as shown in FIG. 5, in the common electrode, different first corner ends 231 are connected through a third connecting portion 252. For example, the first corner end 231 is integrally formed with the third connecting portion 252.

In some embodiments, as shown in FIG. 5, an angle of a second included angle θ₂ formed by the first corner end 231 and the first direction X is 40° to 50°. For example, the second included angle θ₂ is 45°.

So far, an array substrate for a liquid crystal display screen according to some embodiments of the present disclosure is provided. In the above illustrations, the array substrate comprises: a base substrate, agate line, a first insulating layer, a data line, a second insulating layer, a common electrode, and a metal wire. The common electrode comprises a plurality of portions corresponding to a plurality of pixel areas. Each portion comprises a plurality of strip electrodes. A slit is provided between adjacent strip electrodes of the plurality of strip electrodes. Each strip electrode comprises a first main body portion extending along the second direction, a second main body portion extending along a third direction, a first connecting portion extending along a fourth direction, and a second connecting portion extending along a fifth direction. The first main body portion is connected to the first connecting portion, the second main body portion is connected to the second connecting portion, and the first connecting portion is connected to the second connecting portion. The first connecting portion and the second connecting portion form a first included angle. The first main body portion comprises a first corner end. The orthographic projection of the first corner end on the base substrate goes beyond the orthographic projection of the metal wire on the base substrate. In this way, the uneven dark area caused by the first corner end can be away from the pixel area as much as possible. For example, the uneven dark area can enter into the area covered by a black matrix as much as possible. Therefore, in the above-described embodiments, it is possible to reduce the adverse effect of the corner design of the fringe area of the pixel on the display effect, and improve the display effect of the liquid crystal display.

In addition, the inventors of the present disclosure have also found that, since the pixel structure of the 1P2D architecture is used in the related art, a corner area is formed in the middle area of the pixel (as shown at the position B in FIG. 1). Since the liquid crystal molecules in the corner area when subjected to the electric field may deflect towards different directions, it is also likely to form a dark area, thereby reducing the display effect.

In view of this, the inventors of the present disclosure provide that, in some embodiments of the present disclosure, a ratio of a width of the strip electrode 130 to a width of the slit 135 ranges from 0.3 to 0.7. For example, the width ratio is 0.4 or 0.5 and the like. In the case of such width ratio range, it is possible to increase the number of slits, so that the overall light efficiency (i.e., the light transmittance) of the array substrate can be improved, thereby reducing the adverse effect of the above-mentioned dark area on the display effect, and further improving the display effect.

In some embodiments, as shown in FIG. 7, a range of the width W₁ of the strip electrodes 130 is 2 microns≤W₁<2.8 microns. For example, the width of the strip electrode 130 is 2.0 microns or the like. In some embodiments, as shown in FIG. 7, a range of the width W₂ of the slit is 4 microns≤W₂<5.8 microns. For example, the width of the slit is 5.2 microns, 4.4 microns, or 4.0 microns, and the like.

In some embodiments, as shown in FIG. 7, a range of a sum H₁ of projection lengths of the first connecting portion 133 and the second connecting portion 134 on a direction Y perpendicular to the first direction (for example, it may be referred to as the sum of the heights of the first connecting portion 133 and the second connecting portion 134) is 3.9 microns≤H₁<5.9 microns. For example, the sum H₁ of the projection lengths is 3.9 microns or 4.8 microns, and the like. By reducing the sum of the heights of the first connecting portion 133 and the second connecting portion 134, the dark area in the middle area of the electrode is reduced, thereby improving the light efficiency of the liquid crystal.

For example, in some embodiments, the width of the strip electrode 130 is designed to be 2.0 microns, and the width of the slits 135 is designed to be 5.2 microns. Compared with the number of slits of each pixel in the related art, in such design, one slit can be added, so that the overall light efficiency of the liquid crystal display can be improved. In addition, the dimension H₁ at the middle corner of the strip electrode is adjusted from 5.9 microns in the related art to 3.9 microns, so that the light efficiency of the pixel at the middle corner can be improved. In addition, the corner (for example, the first corner) at the fringe of the pixel is stretched outwards by 2.5 microns, so that the light efficiency of the pixel at the fringe position can be improved.

For another example, in other embodiments, the width of the strip electrode 130 is designed to be 2.0 microns, and the width of the slit 135 is designed to be 4.4 microns. Compared with the number of slits of each pixel in the related art, in such design, two slits can be added, so that the overall light efficiency of the liquid crystal display can be improved. In addition, the dimension H₁ at the middle corner of the strip electrode is adjusted from 5.9 microns in the related art to 4.8 microns, so that the light efficiency of the pixel at the middle corner can be improved. In addition, the corner (for example, the first corner) at the fringe of the pixel is stretched outwards by 2.5 microns, so that the light efficiency of the pixel at the fringe position can be improved.

For still another example, in other embodiments, the width of the strip electrode 130 is designed to be 2.0 microns, and the width of the slit 135 is designed to be 4.0 microns. Compared with the number of slits of each pixel in the related art, in such design, two slits can be added, so that the overall light efficiency of the liquid crystal display can be improved. In addition, the dimension H₁ of the strip electrode at the middle corner is adjusted from 5.9 microns in the related art to 3.9 microns, so that the light efficiency of the pixel at the middle corner can be improved. In addition, the corner (for example, the first corner) at the fringe of the pixel is stretched outwards by 2.5 microns and the inclined angle is optimized, so that the light efficiency of the pixel at the fringe position can be improved.

In some embodiments, as shown in FIG. 7, an inner side of a portion where the first connecting portion 133 is connected to the second connecting portion 134 is provided with a concave pattern 311, and an outer side of the portion where the first connecting portion 133 is connected to the second connecting portion 134 is provided with a convex pattern 312. Here, the inner side refers to a side of the portion having an inclined angle of less than 180°, wherein the portion is the portion where the first connecting portion is connected to the second connecting portion; and the outer side refers to a side of the portion having an inclined angle of greater than 180°, wherein the portion is the portion where the first connecting portion is connected to the second connecting portion. For example, an area of the concave pattern 311 is equal to an area of the convex pattern 312. For another example, a shape of the concave pattern 311 is the same as a shape of the convex pattern 312. Of course, those skilled in the art may understand that it is also possible that the area of the concave pattern 311 is not equal to the area of the convex pattern 312, and it is also possible that the shape of the concave pattern 311 is not the same as the area of the convex pattern 312. In the embodiment, a compensation design is realized at the middle corner position of the electrode. In this way, it is possible to prevent the open problem caused by the thin strip electrode as much as possible, and optimize the sharpness of the corner so as to reduce the occurrence of the Trace mura problem.

In some embodiments, as shown in FIG. 7, a range of a length L₁ of the concave pattern 311 along a first direction X (excluding the tip portion of the concave pattern) is 0.5 microns <L₁≤2 microns. A range of a length L2 of the concave pattern 311 along a sixth direction Y is 0.5 microns <L₂≤2 microns. A range of a length L₃ of the convex pattern 312 along a first direction X (excluding the tip portion of the convex pattern) is 0.5 microns <L₃≤2 microns.

Returning to FIGS. 2 and 3, in some embodiments, the array substrate further comprises a gate electrode 112 in the same layer as the gate line 110. The gate electrode 112 is electrically connected to the gate line 110. The first insulating layer 113 also covers the gate electrode 112. For example, a material of the gate electrode 112 comprises a metal such as molybdenum, aluminum, or copper.

In some embodiments, as shown in FIGS. 2, 3 and 4, the array substrate further comprises an active layer 114 and a pixel electrode 46 both on a side of the first insulating layer 113 away from the base substrate 100. The active layer 114 is isolated from the pixel electrode 46. For example, a material of the active layer 114 comprises a semiconductor material such as polysilicon or amorphous silicon.

In some embodiments, as shown in FIGS. 2 and 3, the array substrate further comprises a first electrode (for example, a source) 115 and a second electrode (for example, a drain) 116 both on a side of the active layer 114 away from the first insulating layer 113. The first electrode 115 and the second electrode 116 are both electrically connected to the active layer 114. The second insulating layer 121 also covers the first electrode 115, the second electrode 116, the active layer 114 and the pixel electrode 46. For example, the first electrode 115 is electrically connected to the data line 210. In some embodiments, materials of the first electrode 115 and the second electrode 116 comprises a metal such as molybdenum or aluminum.

In some embodiments, as shown in FIGS. 2 and 6, the second main body portion 132 comprises a second corner end 232. An orthographic projection of the second electrode 116 on the base substrate 100 covers at least a portion of an orthographic projection of the second corner end 232 of a portion of the plurality of strip electrodes 130 on the base substrate. In other words, the orthographic projection of the second electrode 116 on the base substrate 100 overlaps with at least a portion of the orthographic projection of the second corner end 232 of a portion of the plurality of strip electrodes 130 on the base substrate. This is equivalent to stretching the second corner end towards a direction away from the first included angle θ₁, thereby reducing the adverse effect of the dark area caused by the second corner end on the display effect and improving the display effect.

In some embodiments, as shown in FIG. 6, in the common electrode, different second corner ends 232 are connected through a fourth connecting portion 254.

In some embodiments, as shown in FIG. 6, an angle of a third included angle θ₃ formed by the second corner end 232 and the first direction X is 40° to 50°. For example, the third included angle θ₃ is 45°.

In some embodiments, as shown in FIGS. 2, 3 and 4, the array substrate further comprises a first orientation layer 141 covering the common electrode, a liquid crystal layer 150 on a side of the first orientation layer 141 away from the common electrode, and a second orientation layer 142 on a side of the liquid crystal layer 150 away from the first orientation layer 141.

In some embodiments, as shown in FIGS. 2, 3 and 4, the array substrate further comprises a black matrix layer 160 on a side of the second orientation layer 142 away from the liquid crystal layer 150. An orthographic projection of the black matrix layer 160 on the base substrate 100 covers an orthographic projection of the first corner end 231 and a portion of the first main body portion 131 adjacent to the first corner end 231 on the base substrate. In other words, the orthographic projection of the black matrix layer 160 on the base substrate 100 overlaps with the orthographic projection of the first corner end 231 and the portion of the first main body portion 131 adjacent to the first corner end 231 on the base substrate.

In some embodiments, as shown in FIG. 5, a range of a length Lo of the portion of the first main body portion 131 adjacent to the first corner end 231 along the second direction is 0<L₀≤2.5 microns. In this way, it is possible to implement that the first main body portion 131 is stretched towards a direction away from the first included angle, so that the first corner end 231 is away from the pixel area as much as possible, thereby reducing the adverse effect of the dark area caused by the first corner end on the display effect.

In some embodiments, as shown in FIGS. 3 and 4, the array substrate further comprises a color film layer 170 covering the black matrix layer 160 and the second orientation layer 142.

In some embodiments of the present disclosure, a display device is also provided. The display device comprises the array substrate as described previously. For example, the display device may be any product or member having a display function, such as a display panel, a mobile phone, a tablet computer, a television, a display, a notebook computer, a digital photo frame, a navigator, or the like.

Hereto, various embodiments of the present disclosure have been described in detail. Some details well known in the art are not described in order to avoid obscuring the concept of the present disclosure. According to the above description, those skilled in the art would fully understand how to implement the technical solutions disclosed here.

Although some specific embodiments of the present disclosure have been described in detail by way of examples, those skilled in the art should understand that the above examples are only for the purpose of illustration but not for limiting the scope of the present disclosure. It should be understood by those skilled in the art that modifications to the above-described embodiments or equivalently substitution of part of the technical features may be made without departing from the scope and spirit of the present disclosure. The scope of the present disclosure is defined by the appended claims.

1. An array substrate, comprising:
a base substrate;
a gate line located on a side of the base substrate and extending along a first direction;
a first insulating layer covering the gate line;
a data line on a side of the first insulating layer away from the base substrate, the data line and the gate line defining a plurality of pixel areas;
a second insulating layer covering the data line;
a common electrode on a side of the second insulating layer away from the data line, wherein the common electrode comprises a plurality of portions corresponding to the plurality of pixel areas, each portion of the plurality of portions comprising a plurality of strip electrodes, a slit being provided between adjacent strip electrodes of the plurality of strip electrodes, each strip electrode of the plurality of strip electrodes comprising a first main body portion extending along a second direction, a second main body portion extending along a third direction, a first connecting portion extending along a fourth direction and a second connecting portion extending along a fifth direction, the first main body portion being connected to the first connecting portion, the second main body portion being connected to the second connecting portion, the first connecting portion being connected to the second connecting portion, the first connecting portion and the second connecting portion forming a first included angle, and the first main body portion comprising a first corner end; and
a metal wire located in the same layer as the gate line and extending along the first direction, wherein an orthographic projection of the first corner end on the base substrate goes beyond an orthographic projection of the metal wire on the base substrate.

2. The array substrate according to claim 1, wherein a ratio of a width of the each strip electrode to a width of the slit ranges from 0.3 to 0.7.

3. The array substrate according to claim 2, wherein a range of the width Wi of the each strip electrodes is 2 microns≤W₁<2.8 microns.

4. The array substrate according to claim wherein a range of the width W2 of the slit is 4 microns≤W₂<5.8 microns.

5. The array substrate according to claim 2, wherein a range of a sum H₁ of projection lengths of the first connecting portion and the second connecting portion on a direction perpendicular to the first direction is 3.9 microns≤H₁<5.9 microns.

6. The array substrate according to claim 5, wherein an inner side of a portion where the first connecting portion is connected to the second connecting portion is provided with a concave pattern, and an outer side of the portion where the first connecting portion is connected to the second connecting portion is provided with a convex pattern.

7. The array substrate according to claim 6, wherein an area of the concave pattern is equal to an area of the convex pattern.

8. The array substrate according to claim 6, wherein a shape of the concave pattern is the same as a shape of the convex pattern.

9. The array substrate according to claim 1, further comprising:
a gate electrode in the same layer as the gate line, wherein the gate electrode is electrically connected to the gate line, and the gate electrode is covered by the first insulating layer;
an active layer and a pixel electrode both on a side of the first insulating layer away from the base substrate, wherein the active layer is isolated from the pixel electrode; and
a first electrode and a second electrode both on a side of the active layer away from the first insulating layer, wherein the first electrode and the second electrode are electrically connected to the active layer, and the first electrode, the second electrode, the active layer and the pixel electrode are covered by the second insulating layer;
wherein the second main body portion comprises a second corner end, and an orthographic projection of the second electrode on the base substrate covers at least a portion of an orthographic projection of the second corner end of a portion of the plurality of strip electrodes on the base substrate.

10. The array substrate according to claim 9, further comprising:
a first orientation layer covering the common electrode;
a liquid crystal layer on a side of the first orientation layer away from the common electrode;
a second orientation layer on a side of the liquid crystal layer away from the first orientation layer;
a black matrix layer on a side of the second orientation layer away from the liquid crystal layer, wherein an orthographic projection of the black matrix layer on the base substrate covers an orthographic projection of the first corner end and a portion of the first main body portion adjacent to the first corner end on the base substrate; and
a color film layer covering the black matrix layer and the second orientation layer.

11. The array substrate according to claim 10, wherein a range of a length L₀ of the portion of the first main body portion adjacent to the first corner end along the second direction is 0<L₀≤2.5 microns.

12. The array substrate according to claim 1, wherein an angle of a second included angle formed by the first corner end and the first direction is 40° to 50°.

13. The array substrate according to claim 9, wherein an angle of a third included angle formed by the second corner end and the first direction is 40° to 50°.

14. A display device, comprising: the array substrate according to claim 1.
